(19) United States
(12) Patent Application Publication
(10) Pub. No.: US 2017/0141744 A1
(43) Pub. Date: May 18, 2017

(54) FRONT END MODULE

(71) Applicant: Samsung Electro-Mechanics Co., Ltd., Suwon-si (KR)

(72) Inventors: Won Gi KIM, Suwon-si (KR); Sun Hong KIM, Suwon-si (KR)

(73) Assignee: Samsung Electro-Mechanics Co., Ltd., Suwon-si (KR)

(21) Appl. No.: 15/349,110

(22) Filed: Nov. 11, 2016

(30) Foreign Application Priority Data
Nov. 13, 2015 (KR) 10-2015-0160007

(51) Int. Cl. H03F 3/195; H05K 1/11; H05K 1/18; H05K 1/02; H03F 3/24; H05K 5/02

(52) U.S. Cl. CPC H03F 3/195; H03F 3/245; H05K 5/0256; H05K 1/181; H05K 1/021; H05K 1/0243; H05K 1/115; H03F 2200/451; H03F 2200/447; H05K 2201/10166; H04W 88/06

(57) ABSTRACT

A front end module, includes a circuit board; a plurality of electronic components positioned on the circuit board, the electronic components comprising an amplifier configured to amplify a wireless frequency signal, a duplexer and filter configured to filter the wireless frequency signal amplified by the amplifier, and a switch selectively connecting the duplexer and filter with the amplifier; and a heat sink embedded within the circuit board under the amplifier and connected to the amplifier.

### CROSS-REFERENCE TO RELATED APPLICATION(S)

This application claims the benefit under 35 USC 119(a) of Korean Patent Application No. 10-2015-0160007 filed on November 13, 2015, in the Korean Intellectual Property Office, the entire disclosure of which is incorporated herein by reference for all purposes.

### BACKGROUND

1. Field

The present disclosure relates to a front end module.

2. Description Of Related Art

In recent years, it has become advantageous for a single terminal to be able to support communications using different communication networks, for example, a global system for mobile communication (GSM) network or a long term evolution (LTE) network. Such a terminal, supporting both GSM and LTE communications, may include a front end module connected to an antenna terminal. A general front end module may include a switching element connected to an antenna, a duplexer or filter element separating a desired band of a wireless frequency signal transmitted and received by the antenna or passing a specific band, and an amplifier element amplifying the transmitted wireless frequency signal.

When current is consumed, and thus heat is generated by the elements included in the front end module, the generated heat may not only affect the elements generating heat, but may also affect even high frequency characteristics of other elements disposed in the vicinity of the elements within the same circuit board.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to a general aspect, a front end module includes a circuit board; a plurality of electronic components positioned on the circuit board, the electronic components including an amplifier configured to amplify a wireless frequency signal, a duplexer and filter configured to filter the wireless frequency signal amplified by the amplifier, and a switch selectively connecting the duplexer and filter with the amplifier; and a heat sink embedded within the circuit board under the amplifier and connected to the amplifier.

The amplifier may include an integrated transistor, and wherein the heat sink may be substantially centered under a region in which the integrated transistor of the amplifier is located.

The amplifier may include a plurality of integrated transistors, and the heat sink may be substantially centered under the region in which an integrated transistor outputting the amplified wireless frequency signal among the plurality of transistors is located.

The heat sink may be connected to a ground terminal formed on a lower surface of the amplifier element by a via.

The ground terminal may be configured as a ground of an integrated transistor of the amplifier element.

The amplifier may further include a plurality of ground terminals and the plurality of ground terminals may be formed on the lower surface of the amplifier corresponding to a region in which the integrated transistor is located.

The amplifier may further include a plurality of ground terminals and the plurality of ground terminals may be formed on the lower surface of the amplifier.

A control terminal of the amplifier element may be formed on a surface other than the lower surface of the amplifier and may be connected to a circuit pattern on the circuit board by a wire.

The circuit board may further include a build-up laminate including a core layer and an upper build-up layer and a lower build-up layer, respectively positioned on an upper surface and a lower surface of the core layer.

The heat sink may be retained in a cavity penetrating through the core layer.

The heat sink may be retained in a cavity penetrating through the build-up laminate.

The heat sink may be thicker than the core layer.

The front end module may further include a plurality of upper build-up layers and a plurality of lower build-up layers, and the heat sink may be retained in the cavity penetrating through an internal build-up layer adjacent to the core layer.

The heat sink may be positioned to form a space between an inner side wall of the cavity and the heat sink, and an external build-up layer disposed outside the internal build-up layer extends to the inner side wall of the cavity to fill the space.

The heat sink may be formed of one of copper (Cu), aluminum (Al), and invar.

The front end module may further include a plurality of vias configured to thermally and electrically couple the amplifier to the heatsink through a portion of the circuit board.

According to another general aspect, a front end module includes a circuit board; an amplifier secured to a surface of the circuit board; and a heat sink embedded within the circuit board under the amplifier and connected to the amplifier.

The front end module may further include a via traversing through the circuit board, the via configured to thermally couple the amplifier with the heat sink.

The heat sink may include a longitudinally extending metallic block transverse to the circuit board and extending therethrough, the metallic block having a cross-sectional area, co-planar with the circuit board, substantially the same as the amplifier.

The heat sink may be thermally and electrically coupled to a ground of the amplifier.

Other features and aspects will be apparent from the following detailed description, the drawings, and the claims.

### BRIEF DESCRIPTION OF DRAWINGS

FIG. 1 is a perspective view schematically illustrating an example of an electronic device to which a front end module is applied.

FIG. 2 is a block diagram illustrating an example of the front end module.

FIG. 3 is a disposition diagram illustrating a front end module according to an embodiment.

FIG. 4 is a diagram illustrating an example of an amplifier adopted in an amplification circuit of FIG. 2.

FIG. 5 is a cross-sectional view illustrating a front end module according to an embodiment.

FIG. 6 is a cross-sectional view illustrating a coupling between the front end module, according to an embodiment, and a main board.

FIG. 7 is a simulation graph illustrating a temperature change rate according to an embodiment.

FIG. 8 is a simulation graph illustrating parasitic inductance in an amplifier according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Embodiments will now be described in detail with reference to the accompanying drawings.

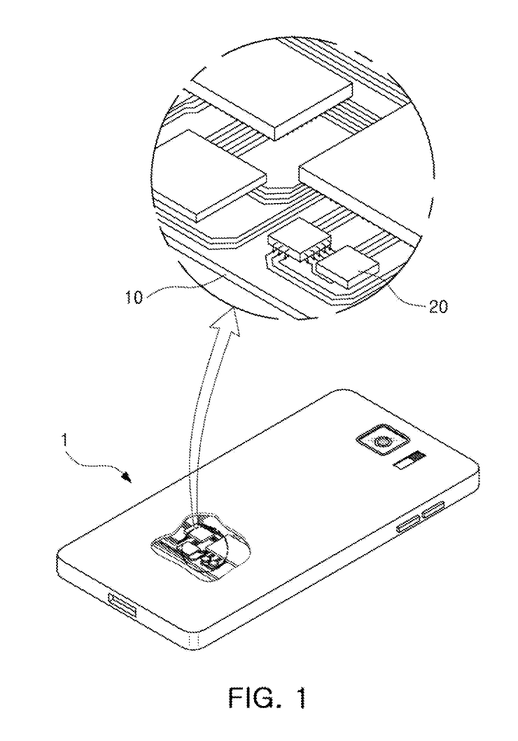

FIG. 1 is a perspective view schematically illustrating an example of an electronic device to which a front end module is applied.

The electronic device, according to the embodiment may include a mobile phone, a personal digital assistant, a digital video camera, a digital still camera, a network system, a computer, a monitor, a television, a video game, a smartwatch, or other devices which would be known to those skilled in the art.

Referring to FIG. 1, the front end module according to an embodiment includes a circuit board 10 and a plurality of interconnected electronic components 20.

The circuit board 10, in an embodiment, is a package board on or in which the plurality of electronic components 20 are mounted or embedded. The circuit board 10 may be a main board or may be mounted on a main board.

The electronic component 20 may be provided in plural, and the plurality of electronic components 20 are disposed on the circuit board 10, or may be disposed in the circuit board 10. The plurality of electronic components 20 are electrically connected through circuit patterns on the circuit board 10 and vias within the circuit board 10. For example, the plurality of electronic components 20 include active elements such as an amplifier, a duplexer, a filter, a switch, and a controller, and passive elements such as a capacitor, an inductor, and a resistor.

The circuit board 10 and the plurality of electronic components 20 are electrically connected to each other, and thus serve as the front end module, transmitting and receiving a wireless frequency signal to and from external communication devices and communication base stations.

The front end module according to an embodiment is configurable for various communication networks such as Code Division Multiple Access (CDMA), Global System for Mobile (GSM), General Packet Radio Service (GPRS), Enhanced Data Gsm Environment (EDGE), Universal Mobile Telecommunications system (UMTS), Wideband Code Division Multiple Access (WCDMA), Long Term Evolution (LTE), and Wireless Broadband Internet (Wibro), and electronic devices performing wireless communications using networks of extended or altered types of the above-mentioned networks. Any above-mentioned wireless communication network may perform wireless communications based on a multiband scheme using various frequency bands.

FIG. 2 is a block diagram illustrating one example of the front end module according to the embodiment.

Referring to FIG. 2, the front end module according to an embodiment includes an antenna switching circuit 21, a filtering circuit 22, a band switching circuit 23, and an amplification circuit 24.

The antenna switching circuit 21 is disposed between an antenna and the filtering circuit 22, and is configured to selectively connect the antenna and each filter and duplexer of the filtering circuit 22 by a switching operation at the time of transmitting and receiving the wireless frequency.

The filtering circuit 22 includes at least one duplexer and filter, in which at least one duplexer separates a transmitted signal and a received signal from the wireless frequency signal received by the antenna, and at least one filter passes and removes components of a specific frequency band from the wireless frequency signal transmitted and received.

Referring to FIG. 2, the filtering circuit 22 includes first to third duplexers 22a, 22b, and 22c and first and second filters 22d and 22e, in which each of the first to third duplexers 22a, 22b, and 22c respectively manipulates wireless frequency signals having different frequency bands, and each of the first and second filters 22d and 22e manipulates wireless frequency signals that use different communication networks.

For example, the first to third duplexers 22a, 22b, and 22c manipulates different frequency bands of the LTE communication network, one of the first and second filters 22d and 22e manipulate a wireless frequency signal that uses the LTE communication network, and the other of the first and second filters 22d and 22e manipulate a wireless frequency signal that uses the GSM communication network.

The band switching circuit 23 performs a switching operation, depending on the frequency band of the wireless frequency signal output from the amplification circuit 24, to select the filter and the duplexer corresponding to the frequency band.

The amplification circuit 24 includes at least one amplifier, in which at least one amplifier amplifies the wireless frequency signal for transmission and transfers the amplified wireless frequency signal to the filter and the duplexer by the band switching circuit 23, or may directly transfer the amplified wireless frequency signal to the filter.

Referring to FIG. 2, the amplification circuit 24 includes first and second amplifiers 24a and 24b, in which the first and second amplifiers 24a and 24b are configured to amplify the wireless frequency signals that use different communication networks. For example, one of the first and second amplifiers 24a and 24b amplifies the wireless frequency signal that is transmitted on the LTE communication network and the other of the first and second amplifiers 24a and 24b amplifies the wireless frequency signal that is transmitted on the GSM communication network.

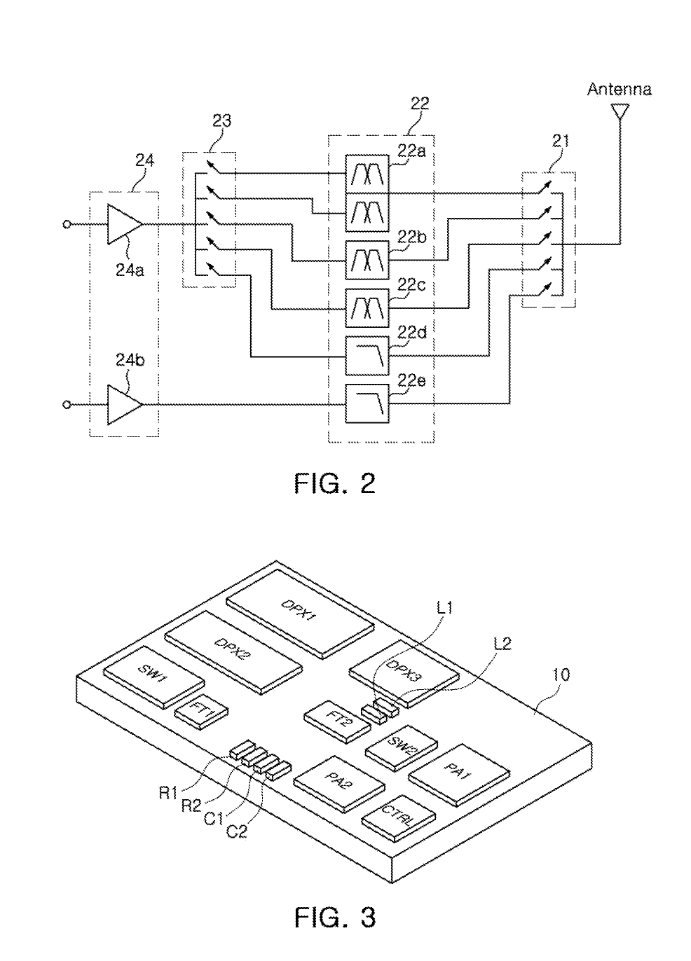

FIG. 3 is a disposition diagram illustrating one example of the front end module.

Referring to FIG. 3, the plurality of electronic components are disposed on the circuit board 10. In detail, the plurality of interconnected electronic components include one or more duplexers DPX1, DPX2, and DPX3, one of more filters FT1 and FT2, one or more amplifier PA1 and PA2, one or more switches SW1 and SW2, one or more capacitors C1 and C2, one or more inductors L1 and L2, and one or more resistors R1 and R2, and may further include a controller CTRL to control active elements such as the one or more duplexers DPX1, DPX2, and DPX3, the one or more filters FT1 and FT2, the one or more amplifier PA1 and PA2, and the one or more switches SW1 and SW2.

The one or more duplexers DPX1, DPX2, and DPX3, the one or more filters FT1 and FT2, the one or more amplifiers PA1 and PA2, and the one or more switches SW1 and SW2, the one or more capacitors C1 and C2, the one or more inductors L1 and L2, the one or more resistors R1 and R2, and the controller CTRL, are electrically connected by the circuit patterns on the circuit board 10 and the vias within the circuit board, and thus serve as the antenna switching circuit 21, the filtering circuit 22, the band switching circuit 23, and the amplification circuit 24, illustrated in FIG. 2.

The one or more duplexers DPX1, DPX2, and DPX3 and the one or more filters FT1 and FT2 of FIG. 3 are interconnected and configured as a filtering circuit, such as the filtering circuit 22 of FIG. 2, and the one or more switches SW1 and SW2 of FIG. 3 are interconnected and configured as an antenna switching circuit and a band switching circuit, such as the antenna switching circuit 21 and the band switching circuit 23 of FIG. 2. Further, the one or more amplifiers PA1 and PA2 are interconnected and configured as an amplification circuit, such as the amplification circuit 24 of FIG. 2.

The active elements such as the one or more duplexers DPX1, DPX2, and DPX3, the one or more filters FT1 and FT2, and the one or more amplifiers PA1 and PA2 generate heat parasitically in response to, or as a byproduct of, current consumption. Problematically, the generated heat may not only negatively affect high frequency characteristics of the active elements generating heat, but may also affect even high frequency characteristics of other active or passive elements disposed in the vicinity of the active elements within the same circuit board. In particular, the problem may be more serious in the amplifiers PA1 and PA2, emitting a considerable portion of consumed power, for example, about 40 to 70% of consumed power, in the form of waste heat.

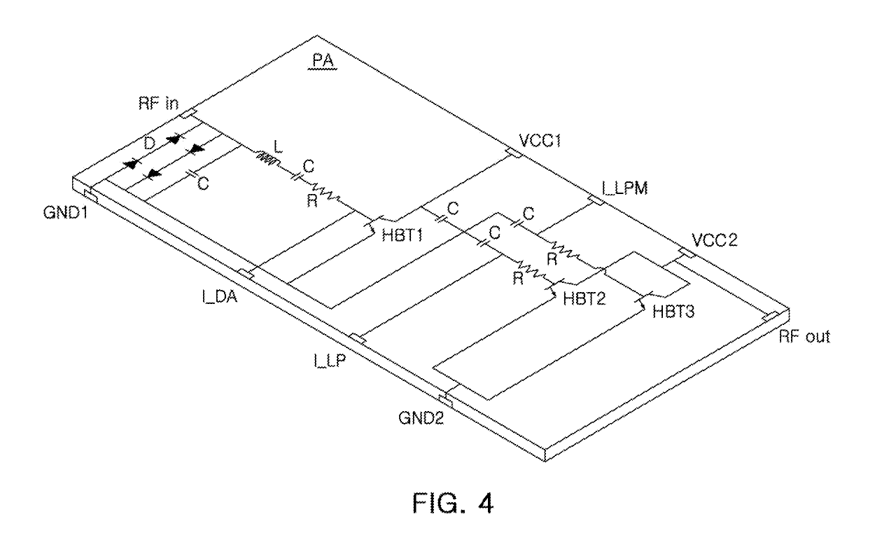

FIG. 4 is a diagram illustrating one example of an amplifier adopted in an amplification circuit, such as the one illustrated in FIG. 2. The amplifier may be implemented by any one amplifier PA of the one or more amplifiers PA1 and PA2 of FIG. 3.

The amplifier PA is, according to an embodiment, an integrated circuit (IC) in which transistors HBT1, HBT2, and HBT3, a plurality of resistors R, a plurality of capacitors C, an inductor L, and a diode D are integrated. The amplifier PA includes a plurality of driving voltage terminals VCC1 and VCC2, bias terminals I_DA, I_LPM, and I_LP, a signal input terminal RF in, a signal output terminal RF out, and one or more ground terminals GND1 and GND2. The driving voltage terminals VCC1 and VCC2, the bias terminals I_DA, I_LPM, and I_LP, the signal input terminal RF in, and the signal output terminal RF out may be individually, or collectively, termed a control terminal.

According to an embodiment, a signal is applied to the plurality of driving voltage terminals VCC1 and VCC2 and the bias terminals I_DA, I_LPM, and I_LP of the amplifier element PA by the resistors and the capacitors, where the capacitors and resistors respectively correspond to capacitors C1 and C2 and resistors R1 and R2 of FIG. 3.

Referring to FIG. 4, the wireless frequency signal input through the signal input terminal RF in is primarily amplified through the first transistor HBT1, may be amplified by the second and third transistors HBT2 and HBT3 to have a final output size, and then may be output to the signal output terminal RF out.

In this case, the first transistor HBT1, performing the primary amplification, is configured as a drive amplifier, and the second and third transistors HBT2 and HBT3, performing the secondary amplification, are configured as power amplifiers.

The embodiment of FIG. 4 illustrates that transistors corresponding to the drive amplifier and the power amplifier(s) are provided either singly or in pairs, but the number of transistors configuring the drive amplifier and the power amplifier may be changed.

Referring to FIG. 4, because a voltage or current level of the driving voltage terminal VCC2 and the bias terminals I_LPM and I_LP of the power amplifier that outputs the final wireless frequency signal is higher than that of the driving voltage terminal VCC1 and the bias terminal I_DA of the drive amplifier, most heat is generated by the second and third transistors HBT2 and HBT3 during the amplification of the wireless frequency signal.

In the front end module according to one or more embodiments, a heat sink connected to the second and third transistors HBT2 and HBT3 is provided in the circuit board to efficiently dissipate heat generated by the second and third transistors HBT2 and HBT3.

The heat sink is, for example, disposed in a lower portion of the board in the mounting direction of the amplifier element in which the second and third transistors HBT2 and HBT3 are integrated, to thereby minimize a transfer path of heat. In other words, the heat sink is, for example, positioned to correspond with the second and third transistors HBT2 and HBT3. According to one or more embodiments, the heat sink corresponds with both X and Y coordinates of the transistors, but may be positioned inside the circuit board 10, or on an inverse, obverse, or opposing face of the circuit board 10. The heat sink absorbs the heat generated by the second and third transistors HBT2 and HBT3 through vias, to pass through the circuit board 10, and may distribute the absorbed heat to other paths connected to the heat sink. For example, the heat sink is connected to the circuit patterns on the main board on which the circuit board is mounted, to dissipate the absorbed heat.

The heat sink, according to an embodiment, is connected to the ground terminals GND1 and GND2 of the amplifier element PA by the vias. In particular, the heat sink is connected to the ground terminals GND2 of the second and third transistors HBT2 and HBT3, which are a cause of heat generation, by the plurality of vias.

The ground terminals GND2 of the second and third transistors HBT2 and HBT3, according to an embodiment, are provided in plural, and the plurality of ground terminals GND2 are formed over a lower surface of the amplifier element PA or formed on the lower surface of the amplifier element corresponding to a region in which the integrated second and third transistors HBT2 and HBT3 are disposed, and thus may be connected to the heat sink by the vias.

To maintain the voltage of the ground terminals GND1 and GND2 as a ground voltage, the heat sink is connected, for example, to a ground conductive pattern on the main board on which the circuit board is mounted.

According to an embodiment, the heat sink, having a sufficient volume according to the expected heat generation and the environment, is connected to the ground conductive pattern on the main board to improve ground characteristics, to thereby remove parasitic components that may be caused between emitter terminals of the second and third transistors HBT2 and HBT3 and the ground, and to improve an amplification gain of the amplifier element.

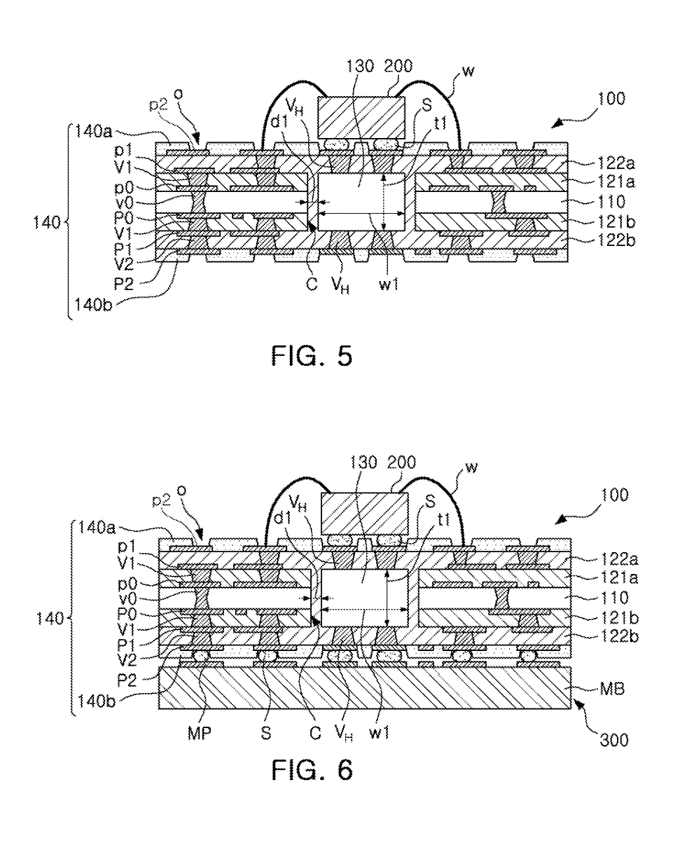

FIG. 5 is a cross-sectional view illustrating a front end module according to an embodiment, and FIG. 6 is a cross-sectional view illustrating a coupling between the front end module and a main board.

Referring to FIG. 5, a circuit board 100 according to an embodiment includes a core layer 110, an upper first build-up layer 121a and an upper second build-up layer 122a that are disposed on an upper surface of the core layer 110, and a lower first build-up layer 121b and a lower second build-up layer 122b that are disposed on a lower surface of the core layer 110.

A structure including the core layer 110, the upper first and second build-up layers 121a and 122a, and the lower first and second build-up layers 121b and 122b that are used in the circuit board 100, are termed a build-up laminate. Further, the upper first build-up layer 121a and the lower first build-up layer 121b that are adjacently disposed to the core layer 110 are collectively termed an internal build-up layer, and the upper second build-up layer 122a and the lower second build-up layer 122b, that are disposed outside the internal build-up layer, are collectively termed an external build-up layer.

The core layer 110, according to an embodiment, has a conductive pattern p0 disposed on the upper surface and P0 disposed on the lower surface of the core layer 110 and an inner-layer circuit including a conductive via v0 penetrating through the core layer 110 and providing electrical and thermal conduction between the upper and lower surfaces thereof. The core layer 110 is formed of a material having high rigidity, in order to prevent the circuit board 100 from becoming warped.

For example, the core layer 110 is formed of an insulating resin in which a reinforcing material such as prepreg, glass, or a metal like invar is impregnated. The reinforcing material may be a glass fiber or a metal material and the insulating resin may be a resin like bismaleimide triazine or epoxy. When the core layer 110 is formed of metal, a surface on which the inner-layer circuit will be formed may be coated with an insulating material.

The upper first build-up layer 121a and the lower first build-up layer 121b include an outer-layer circuit including a conductive pattern p1 and P1, respectively, and corresponding conductive vias V1, and the upper second build-up layer 122a and the lower second build-up layer 122b include an outer-layer circuit including a conductive pattern p2 and P2, respectively and corresponding conductive vias V2.

The upper first and second build-up layers 121a and 122a and the lower first and second build-up layers 121b and 122b are formed, for example, of an insulating material to electrically insulate between circuits. For example, the insulating material includes a thermosetting resin like epoxy resin or a thermoplastic resin like polyimide. In a specific example, the upper first and second build-up layers 121a and 122a and the lower first and second build-up layers 121b and 122b are also formed of a photo-curable insulating resin, such as a photosensitive insulating film.

The conductive patterns p0, P0, p1, P1, p2, and P2 and/or the conductive vias v0, v1, and v2 include, for example, any one or any combination of two or more of: copper (Cu), aluminum (Al), silver (Ag), tin (Sn), gold (Au), nickel (Ni), lead (Pd), or an alloy thereof. In a specific example, the conductive patterns p0, P0, p1, P1, and p2 are formed from a copper (Cu) foil.

A cavity C, according to an embodiment, penetrates through the build-up laminate and an inside of the cavity C is provided with a heat sink 130. The heat sink 130 is formed of a material having excellent thermal conductivity. For example, the heat sink 130 is formed of copper (Cu), aluminum (Al), or invar and may be illustrated as a rectangular parallelepiped block, but may also be disposed in various other shapes.

The cavity C for disposing the heat sink 130, according to one or more embodiments, penetrates through a portion of the build-up laminate. As an example, the cavity C penetrates through the core layer 110, and, as another example, the cavity C penetrates through the upper first build-up layer 121a and the lower first build-up layer 121b, as well as through the core layer 110. When the cavity C penetrates through the upper first build-up layer 121a and the lower first build-up layer 121b, as well as the core layer 110, the heat sink 130 may at least have a thickness t1, larger than that of the core layer 110.

As illustrated in FIG. 5, the thickness t1 of the heat sink 130 substantially corresponds to a depth of the cavity C. By doing so, the heat sink 130 has a sufficient volume (and surface area) to improve heat dissipation characteristics.

The heat sink 130 disposed in the cavity C, according to one or more embodiments, is supported in the cavity C by a formation material of the upper second build-up layer 122a and the lower second build-up layer 122b, which are located at an outermost position. In other words, the heat sink 130 is sandwiched between the upper and lower second build-up layers 122a and 122b, respectively.

A width w1 of the heat sink 130 is designed to be smaller than that of the cavity C, and thus the heat sink is disposed at a predetermined interval d1 from an inner side wall of the cavity C. The upper second build-up layer 122a and the lower second build-up layer 122b, according to one or more embodiments, extend to be filled in a space between the inner side wall of the cavity C and the heat sink 130, to firmly fix the heat sink 130 in the cavity C.

The upper second build-up layer 122a and the lower second build-up layer 122b that are located at the outermost portion, according to one or more embodiments, include one or more vias, e.g. V_{H} for heat dissipation. One or more of the vias, V_{H}, for heat dissipation are directly connected to the heat sink 130 and are connected to a conductive pattern p2 and/or P2, exposed on one or more of the surfaces of the circuit board 100.

The upper and lower surfaces of the heat sink 130, according to one or more embodiments, are each connected to a plurality of vias V_{H} for heat dissipation. The plurality of vias V_{H} for heat dissipation connected to the upper surface of the heat sink 130 contact an electronic component 200 mounted on one surface of the circuit board 100 through the conductive pattern p2 and a solder S, and the plurality of vias V_{H} for heat dissipation connected to the lower surface of the heat sink 130 contact a main board 300 on which the circuit board 100 is mounted through the conductive pattern P2 and the solder S. The heat sink 130 is located within the board adjacent to the electronic component 200 to quickly absorb heat generated by the electronic component 200 and to dissipate the absorbed heat through the main board 300, which is connected to the heat sink.

A circuit pattern MP formed on a base substrate MB of the main board 300, connected to the heat sink 130, according to one or more embodiments, is a ground conductive pattern. When the heat sink 130, having a sufficient volume, is connected to the ground conductive pattern MP of the main board 300, ground characteristics may be improved. By doing so, the parasitic component, which may appear between the emitter terminal of the transistor integrated in the amplifier PA and the ground, is removed, and the amplification gain of the amplifier element PA is improved.

The circuit board 100, according to one or more embodiments, includes an outer layer 140. The outer layer 140 includes first and second outer layers 140a and 140b, each disposed on the surfaces of the upper second build-up layer 122a and the lower second build-up layer 122b, respectively, which are located at the outermost portion. The outer layer 140 is, for example, a solder resist layer. The outer layer 140 has a plurality of openings o through which a region to be connected to an external circuit or electronic components (not illustrated) among the conductive patterns p2 and/or P2, located at the outermost portion, is exposed. The conductive pattern p2 and/or P2, connected to the via, V_{H}, for heat dissipation may be exposed to the surface of the circuit board 100 through a portion of the plurality of openings o.

The above-mentioned embodiment illustrates that two build-up layers are formed on each surface of the core layer 100, but one build up layer or three or more build-up layers may be formed, and therefore the cavity structure may be variously changed as would be apparent to one of skill in the art after gaining a thorough understanding of the instant disclosure.

FIGS. 5 and 6 schematically illustrate one electronic component 200 mounted on the circuit board 100. In addition, as illustrated in FIG. 3, a plurality of electronic components may also be mounted on the circuit board.

However, the heat sink 130 may be provided in a portion of the space in the circuit board 100, and the electronic component 200 disposed over the heat sink 130 may be an electronic component having a high heat generation value among the plurality of electronic components. For example, the electronic component 200, mounted over the heat sink 130, may be one or more amplifiers PA1 and PA2 of FIG. 3. The plurality of heat sinks 130 formed in the circuit board 100 are, for example, disposed under one or more amplifiers PA1 and PA2, respectively.

Hereinafter, for convenience of explanation, an embodiment will be described in the case where the electronic component disposed over the heat sink 130 is the amplifier element PA. However, such a description is merely an example, and the description is not limited thereto.

Heat is likely to be generated by the operation of the amplifier element PA. The amplifier element PA may generate relatively more heat than is generated in other regions, and therefore the amplifier element PA may have a high temperature region, i.e., a hot spot. The hot spot may be formed at one point or at a plurality of points of the amplifier element PA. In particular, the hot spot may be formed in a region in which switches of the amplifier element PA are relatively dense. More specifically, referring to FIG. 4, in the amplifier element PA, a portion in which the integrated second and third transistors outputting the amplified wireless frequency signal are located represent a hot spot region.

According to an embodiment, the hot spot of the amplifier element PA is substantially centered over the heat sink 130. Therefore, the heat sink 130 acts to effectively receive the heat generated by the hot spot.

According to an embodiment, substantially all of the area of the amplifier element PA, as well as the hot spot of the amplifier element PA, may be positioned or centered over the heat sink 130. To effectively capture and transmit this waste heat, the area of the heat sink 130, according to one or more embodiments, is equal to or greater than that of the amplifier element PA, positioned over the heat sink 130. For example, an area of the upper surface of the heat sink 130 is about 1.0 mm×0.9 mm, and an area of the amplifier element PA is about 1.0 mm×0.8 mm or about 1.0 mm×0.9 mm. In this case, the amplifier element PA having an area equal to or smaller than that of the heat sink 130 is disposed in a region of the upper surface of the heat sink 130, and thus, substantially all of the heat generated by the amplifier element PA is quickly transferred to the heat sink 130.

As described above, the heat sink 130 is connected to the ground terminals GND1 and GND2 of the amplifier element PA, illustrated in FIG. 3, through the vias. In particular, the heat sink 130 is connected to the plurality of ground terminals GND2 of the second and third transistors HBT2 and HBT3, which are a substantial cause of heat generation, by the plurality of vias V_{H}.

When the plurality of ground terminals GND2 are formed over the lower surface of the amplifier PA, the driving voltage terminals VCC1 and VCC2, the bias terminals I_DA, I_LPM, and I_DA, and the signal input/output terminals RF in and RF out(which correspond to the control terminal of the amplifier PA) are formed on a portion other than the lower surface of the amplifier PA and instead, are formed, for example, on the upper surface of the amplifier PA. In other words, the control terminals are formed on an opposing surface of the amplifier PA than the ground terminals. As another example, the control terminals may be formed on lateral surfaces of the amplifier PA. The driving voltage terminals VCC1 and VCC2, the bias terminals I_DA, I_LPM, and I_LP, and the signal input/output terminals RF in and RF out that are formed on the upper surface of the amplifier element PA, according to one or more embodiments, are connected to the conductive pattern p2 on the circuit board 100 by a wire w.

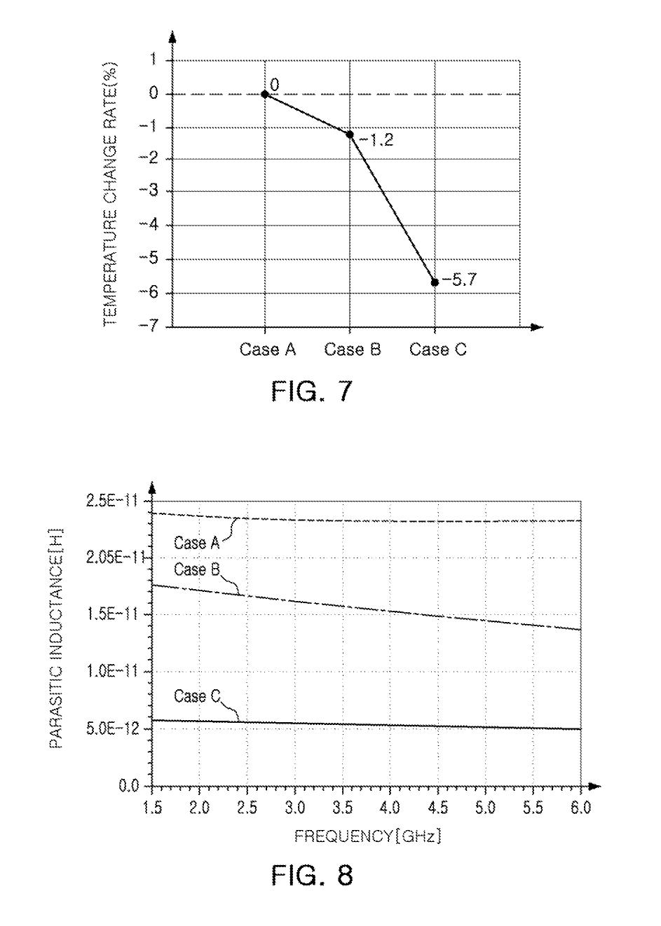

FIG. 7 is a simulation graph illustrating a temperature change rate, according to an embodiment, and FIG. 8 is a simulation graph illustrating parasitic inductance in the amplifier element, according to an embodiment.

In FIGS. 7 and 8, Case A is a graph illustrating a temperature change rate at the electronic component 200 when, instead of the heat sink according to an embodiment, vias are disposed at a low density, Case B is a graph illustrating a temperature change rate when, instead of the heat sink according to an embodiment, vias are disposed at a high density, and Case C is a graph illustrating a temperature change rate when the heat sink, according to an embodiment, is employed.

Case A is a graph of the case in which 48 vias, having a diameter of about 65 μm, are disposed on an area of 1.4 mm×1.0 mm at a pitch interval of about 165 μm, Case B is a graph of the case in which 88 vias, having a diameter of about 65 μm, are disposed on an area of 1.4 mm×1.0 mm at a pitch interval of about 125 μm, instead of the heat sink, according to an embodiment, and Case C is a graph of the case in which the heat sink, according to an embodiment, is disposed on an area of 1.4 mm×1.0 mm.

Referring to FIG. 7, it may be appreciated that the temperature change rate of Case A is about 0%, and thus very little heat generated by the electronic components is emitted when the vias are disposed at a low density, while the temperature change rate of Case B is about 1.2% Thus, the heat generated by the electronic components is transferred in relatively small amounts in the case that the vias are disposed at a relatively high density.

On the other hand, the temperature change rate of Case C, according to one or more embodiments, in which the heat sink having a sufficient volume and surface area quickly absorbs the heat generated by the electronic components, is about −5.7%. As a result, it may be appreciated that the heat generated by the electronic components is more effectively transferred in this embodiment, compared with Cases A and B, in which the vias are disposed at a low density or even a high density.

Referring to FIG. 8, the parasitic inductance may correspond to the parasitic component generated between the emitter terminals of the second and third transistors HBT2 and HBT3 described with reference to FIG. 4 and the ground.

In FIG. 8, the parasitic inductance near 2.0 GHz of Case A is 2.4*10⁻¹¹ [H], the parasitic inductance near 2.0 GHz of Case B is 1.75*10⁻¹¹ [H], and thus the parasitic inductance component may be relatively high, but the parasitic inductance near 2.0 GHz of Case C in which the heat sink having a sufficient volume is connected to the ground conductive pattern to improve the ground characteristics is 5.0*10⁻¹² [H]. As a result, it may be appreciated that the parasitic inductance component is remarkably reduced, compared with Cases A and B.

The following Table 1 shows the amplification gain according to an embodiment.

TABLE 1

| | Frequency (MHz) | Gain (dB) |
|---|---|---|
| Case A | 1920 | 32.35 |
| | 1950 | 32.08 |
| | 1980 | 31.67 |
| Case B | 1920 | 32.5 |
| | 1950 | 32.34 |
| | 1980 | 32.06 |
| Case C | 1920 | 33.35 |
| | 1950 | 33.43 |
| | 1980 | 33.39 |

Referring to the above Table 1, Case A has an amplification gain of 32.35 dB at a frequency 1920 MHz, Case B has an amplification gain of 32.5 dB at a frequency 1920 MHz, and Case C has an amplification gain of 33.35 dB at a frequency 1920 MHz. Further, Case A has an amplification gain of 32.08 dB at a frequency 1950 MHz, Case B has an amplification gain of 32.34 dB at a frequency 1950 MHz, and Case C has an amplification gain of 33.43 dB at a frequency 1950 MHz. Further, Case A has an amplification gain of 31.67 dB at a frequency 1980 MHz, Case B has an amplification gain of 32.06 dB at a frequency 1980 MHz, and Case C has an amplification gain of 33.39 dB at a frequency 1980 MHz. That is, it may be appreciated that Case C increases the amplification gain of the amplifier element in response to the reduction in the parasitic inductance component, compared with Cases A and B.

As set forth above, according to one or more embodiments, it is possible to improve the high frequency and thermal transfer characteristics of the front end module using the heat sink having sufficient volume as the ground.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A front end module, comprising:
a circuit board;
electronic components positioned on the circuit board and comprising an amplifier configured to amplify a wireless frequency signal, a duplexer and filter configured to filter the amplified wireless frequency signal, and a switch selectively connecting the duplexer and filter with the amplifier; and
a heat sink embedded within the circuit board, disposed under and connected to the amplifier.

2. The front end module of claim 1, wherein the amplifier comprises an integrated transistor, and the heat sink is disposed under a region in which the integrated transistor of the amplifier is located.

3. The front end module of claim 2, wherein the amplifier comprises integrated transistors, and
the heat sink is disposed under the region in which an integrated transistor outputting the amplified wireless frequency signal among the integrated transistors is located.

4. The front end module of claim 1, wherein the heat sink is connected to a ground terminal formed on a lower surface of the amplifier by a via.

5. The front end module of claim 4, wherein the ground terminal is configured as a ground of an integrated transistor of the amplifier.

6. The front end module of claim 5, wherein the amplifier further comprises ground terminals formed on the lower surface of the amplifier and corresponding to a region in which the integrated transistor is located.

7. The front end module of claim 5, wherein the amplifier further comprises a plurality of ground terminals and the plurality of ground terminals are formed on the lower surface of the amplifier.

8. The front end module of claim 7, wherein a control terminal of the amplifier is formed on a surface other than the lower surface of the amplifier and is connected to a circuit pattern on the circuit board by a wire.

9. The front end module of claim 1, wherein the circuit board further comprises a build-up laminate comprising a core layer and an upper build-up layer and a lower build-up layer, respectively positioned on an upper surface and a lower surface of the core layer.

10. The front end module of claim 9, wherein the heat sink is retained in a cavity penetrating through the core layer.

11. The front end module of claim 9, wherein the heat sink is retained in a cavity penetrating through the build-up laminate.

12. The front end module of claim 11, wherein the heat sink is thicker than the core layer.

13. The front end module of claim 11, further comprising:
upper build-up layers and lower build-up layers, wherein the heat sink is retained in the cavity penetrating through an internal build-up layer adjacent to the core layer.

14. The front end module of claim 13, wherein the heat sink is positioned to form a space between an inner side wall of the cavity and the heat sink, and an external build-up layer disposed outside the internal build-up layer extends to the inner side wall of the cavity to fill the space.

15. The front end module of claim 1, wherein the heat sink is formed of one of copper (Cu), aluminum (Al), and invar.

16. The front end module of claim 1, further comprising:
a plurality of vias configured to thermally and electrically couple the amplifier to the heatsink through a portion of the circuit board.

17. A front end module, comprising:
a circuit board;
an amplifier secured to a surface of the circuit board; and
a heat sink embedded within the circuit board under the amplifier and connected to the amplifier.

18. The front end module of claim 17, further comprising:
a via traversing through the circuit board, the via configured to thermally couple the amplifier with the heat sink.

19. The front end module of claim 17, wherein the heat sink comprises a longitudinally extending metallic block transverse to the circuit board and extending therethrough, the metallic block having a cross-sectional area, co-planar with the circuit board, substantially the same as the amplifier.

20. The front end module of claim 17, wherein the heat sink is thermally and electrically coupled to a ground of the amplifier.
